(19) United States
(12) Patent Application Publication
(10) Pub. No.: US 2024/0081001 A1
(43) Pub. Date: Mar. 7, 2024

(54) DISPLAY DEVICE

(71) Applicant: Samsung Display Co., LTD., Yongin-si (KR)

(72) Inventors: Soh Ra HAN, Yongin-si (KR); Yong Hyuck LEE, Yongin-si (KR); Hong Kwan LEE, Yongin-si (KR); Hyun Jun CHO, Yongin-si (KR); Min Ji KIM, Yongin-si (KR); Sung Woo EO, Yongin-si (KR); Eun Gil CHOI, Yongin-si (KR); Sang Woo HAN, Yongin-si (KR)

(73) Assignee: Samsung Display Co., LTD., Yongin-si (KR)

(21) Appl. No.: 18/309,876

(22) Filed: May 1, 2023

(30) Foreign Application Priority Data
Sep. 1, 2022 (KR) 10-2022-0110685

(51) Int. Cl. H05K 5/02; D02G 3/44

(52) U.S. Cl. CPC H05K 5/02; D02G 3/447; D10B 2401/063; D10B 2505/02

(57) ABSTRACT

A display device includes a display panel having a folding axis extending in a first direction; and a panel supporter disposed on a surface of the display panel. The panel supporter includes a first layer including a first base resin and first fiber yarns extending in the first direction and dispersed in the first base resin, a second layer disposed on the first layer, the second layer including a second base resin and second fiber yarns extending in a second direction intersecting the first direction and dispersed in the second base resin, and a third layer disposed on the second layer, the third layer including a third base resin and third fiber yarns extending in the first direction and dispersed in the third base resin.

### CROSS-REFERENCE TO RELATED APPLICATION(S)

This application claims priority to and benefits of Korean Patent Application No. 10-2022-0110685 under 35 U.S.C. § 119, filed on Sep. 1, 2022, in the Korean Intellectual Property Office (KIPO), the entire contents of which are incorporated herein by reference.

### BACKGROUND

### 1. Technical Field

Embodiments relate to a display device with a bendable panel supporter.

### 2. Description of the Related Art

The importance of a display device has been increasing with the development of multimedia. Accordingly, various types of display devices such as an organic light emitting display (OLED) and a liquid crystal display (LCD) have been used.

Recently, with the development of display technology, research and development of display devices having flexible displays have been actively conducted. The flexible display may extend or reduce a display screen, for example, fold, bend, or slide the display screen, thereby significantly contributing to a decrease in volume or a change in design of the display device.

For example, since a load of the display device itself may be reduced by using fiber reinforced plastics (FRP) as a panel supporter for supporting the flexible display of the display device, research and development on technologies for manufacturing the panel supporter with fiber reinforced plastics have been actively conducted.

### SUMMARY

Embodiments provide a display device capable of improving the surface quality of a panel supporter.

However, embodiments are not limited to those set forth herein. The above and other embodiments will be apparent to one of ordinary skill in the art to which the disclosure pertains by referencing the detailed description of the disclosure given below.

According to an embodiment, a display device may include a display panel having a folding axis extending in a first direction; and a panel supporter disposed on a surface of the display panel. The panel supporter may include a first layer including a first base resin and first fiber yarns extending in the first direction and dispersed in the first base resin, a second layer disposed on the first layer, the second layer including a second base resin and second fiber yarns extending in a second direction intersecting the first direction and dispersed in the second base resin, and a third layer disposed on the second layer, the third layer including a third base resin and third fiber yarns extending in the first direction and dispersed in the third base resin. The number of the second fiber yarns per unit volume of the second layer may be greater than the number of the first fiber yarns per unit volume of the first layer and the number of the third fiber yarns per unit volume of the third layer.

A diameter of each of the second fiber yarns may be smaller than a diameter of each of the first fiber yarns and a diameter of each of the third fiber yarns.

The diameter of each of the first fiber yarns and the diameter of each of the third fiber yarns may be same as each other.

A spaced distance between the second fiber yarns in the second layer may be smaller than a spaced distance between the first fiber yarns in the first layer and a spaced distance between the third fiber yarns in the third layer.

The diameter of each of the second fiber yarns may be about 4.5 μm or more and about 5.5 μm or less. The diameter of each of the first fiber yarns and the diameter of each of the third fiber yarns may be about 6.5 μm or more and about 7.5 μm or less.

A thickness of the second layer may be greater than a thickness of the first layer and a thickness of the third layer.

The second layer may be disposed between the first layer and the third layer.

The thickness of the first layer and the thickness of the third layer may be same as each other.

The first fiber yarns, the second fiber yarns and the third fiber yarns may include carbon. A carbon content of each of the second fiber yarns may be greater than a carbon content of each of the first fiber yarns and a carbon content of each of the third fiber yarns.

An elastic modulus of each of the second fiber yarns may be greater than an elastic modulus of each of the first fiber yarns and an elastic modulus of each of the third fiber yarns.

According to an embodiment, a display device may include a display panel having a folding axis extending in a first direction, and a panel supporter disposed on a surface of the display panel. The panel supporter may include a first layer including a first base resin and first fiber yarns extending in the first direction and dispersed in the first base resin, a second layer disposed on the first layer, the second layer including a second base resin and second fiber yarns extending in a second direction intersecting the first direction and dispersed in the second base resin, and a third layer disposed on the second layer, the third layer including a third base resin and third fiber yarns extending in the first direction and dispersed in the third base resin. An elastic modulus of each of the second fiber yarns may be greater than an elastic modulus of each of the first fiber yarns and an elastic modulus of each of the third fiber yarns.

The elastic modulus of each of the first fiber yarns and the elastic modulus of each of the third fiber yarns may be same as each other.

A thickness of the second layer may be greater than a thickness of the first layer and a thickness of the third layer.

The second layer may be disposed between the first layer and the third layer.

The elastic modulus of each of the second fiber yarns may be about 290 GPa or more. The elastic modulus of each of the first fiber yarns and the elastic modulus of each of the third fiber yarns may be about 240 GPa or less.

According to an embodiment, a display device may include a display panel having a folding axis extending in a first direction and a panel supporter disposed on a surface the display panel. The panel supporter may include a first layer including a first base resin and first fiber yarns extending in the first direction and dispersed in the first base resin, a second layer disposed on the first layer, the second layer including a second base resin and second fiber yarns extending in a second direction intersecting the first direction and dispersed in the second base resin, and a third layer disposed on the second layer, the third layer including a third base resin and third fiber yarns extending in the first direction and dispersed in the third base resin. A carbon content of each of the second fiber yarns may be greater than a carbon content of each of the first fiber yarns and a carbon content of each of the third fiber yarns.

The carbon content of each of the first fiber yarns and the carbon content of each of the third fiber yarns may be same as each other.

A thickness of the second layer may be greater than a thickness of the first layer and a thickness of the third layer.

The second layer may be disposed between the first layer and the third layer.

The carbon content of each of the second fiber yarns may be about 96% or more. The carbon content of each of the first fiber yarns and the carbon content of each of the third fiber yarns may be about 93% or less.

According to an embodiment, a display device may include a display panel having a folding axis extending in a first direction, and a panel supporter disposed on a surface of the display panel and including a base resin and fiber yarns dispersed in the base resin. The fiber yarns may include first fiber yarns extending in the first direction, second fiber yarns extending in a second direction intersecting the first direction, and third fiber yarns extending in the first direction. The base resin may include a first portion in which the first fiber yarns are dispersed, a second portion disposed on the first portion, the second fiber yarns being dispersed in the second portion, and a third portion disposed on the second portion, the third fiber yarns being dispersed in the third portion. The number of the second fiber yarns per unit volume of the second portion may be greater than the number of the first fiber yarns per unit volume of the first portion and the number of the third fiber yarns per unit volume of the third portion.

A diameter of each of the second fiber yarns may be smaller than a diameter of each of the first fiber yarns and a diameter of each of the third fiber yarns.

A spaced distance between the second fiber yarns in the second portion may be smaller than a spaced distance between the first fiber yarns in the first portion and a spaced distance between the third fiber yarns in the third portion.

According to an embodiment, a surface quality of the panel supporter may be improved.

Other features and embodiments may be apparent from the following detailed description and the drawings.

### BRIEF DESCRIPTION OF THE DRAWINGS

The accompanying drawings, which are included to provide a further understanding of the disclosure, illustrate embodiments in which:

FIG. 1 is a schematic perspective view illustrating a display device according to an embodiment;

FIG. 2 is a schematic perspective view illustrating a state in which the display device according to an embodiment is folded;

FIG. 3 is a schematic side view illustrating a structure of the display device according to an embodiment;

FIG. 4 is a schematic plan view illustrating a panel supporter of the display device according to an embodiment;

FIG. 5 is a schematic cross-sectional view illustrating a cross section taken along line X1-X1′ of FIG. 4;

FIG. 6 is a schematic cross-sectional view illustrating a cross section taken along line X2-X2′ of FIG. 4;

FIG. 7 is a schematic view for describing a process of manufacturing the panel supporter of the display device according to an embodiment;

FIG. 8 is an image obtained by photographing a cross-section of the panel supporter of the display device according to an embodiment, viewed from a first direction;

FIG. 9 is an image obtained by photographing a cross-section of the panel supporter of the display device according to an embodiment, viewed from a second direction;

FIG. 10 is a graph illustrating a surface step for each position of the panel supporter of the display device according to an embodiment;

FIG. 11 is a schematic cross-sectional view illustrating a structure of a panel supporter of a display device according to a comparative example;

FIG. 12 is a schematic cross-sectional view illustrating a structure of a panel supporter of a display device according to a comparative example;

FIG. 13 is an image obtained by photographing a cross-section of the panel supporter of the display device according to an embodiment, viewed from a second direction;

FIG. 14 is a graph illustrating a surface step for each position of a panel supporter of a display device according to an embodiment;

FIG. 15 is a schematic cross-sectional view illustrating a structure of a panel supporter of a display device according to another embodiment;

FIG. 16 is a schematic cross-sectional view illustrating a structure of the panel supporter of the display device according to the embodiment of FIG. 15; and

FIG. 17 is a graph illustrating a surface step for each position of the panel supporter of the display device according to the embodiment of FIG. 15.

### DETAILED DESCRIPTION OF THE EMBODIMENTS

The embodiments will now be described more fully hereinafter with reference to the accompanying drawings. The embodiments may, however, be provided in different forms and should not be construed as limiting. The same reference numbers indicate the same components throughout the disclosure. In the accompanying figures, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on another layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within about ±30%, 20%, 10%, 5% of the stated value.

In the description, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the description, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the description.

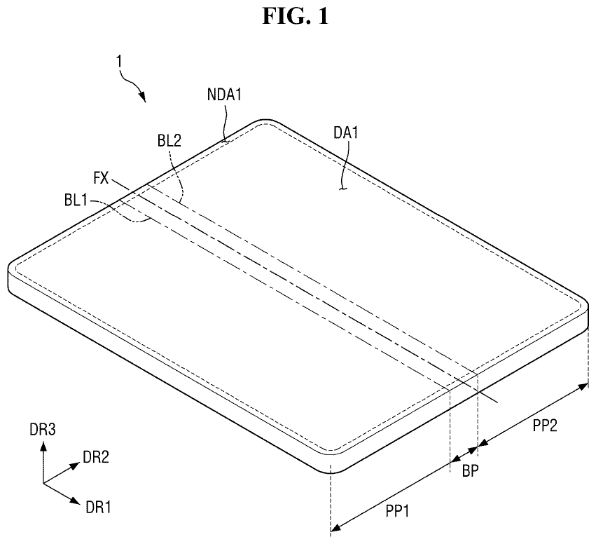

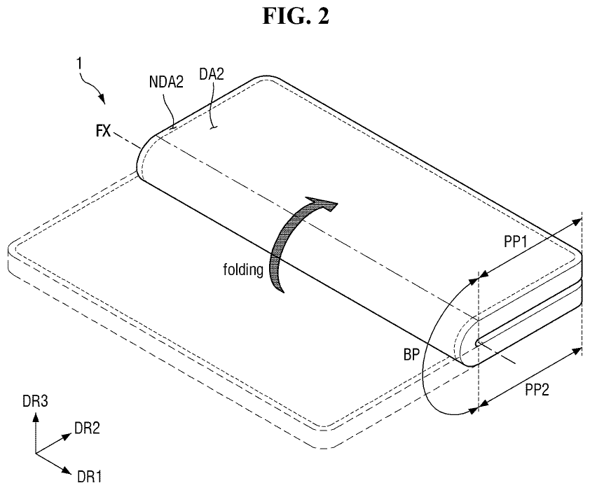

FIG. 1 is a schematic perspective view illustrating a display device according to an embodiment. FIG. 2 is a schematic perspective view illustrating a state in which the display device according to an embodiment is folded.

FIG. 1 illustrates a first state of the display device 1 that is unfolded without being bent with respect to a folding axis FX, and FIG. 2 illustrates a second state of the display device 1 bent with respect to the folding axis FX.

Referring to FIGS. 1 and 2, the display device 1 according to an embodiment is a device that displays a moving image or a still image, and may be used as a display screen of various products such as televisions, laptops, monitors, billboards, and Internet of Things, as well as portable electronic devices such as mobile phones, smart phones, tablet PCs, smart watches, watch phones, mobile communication terminals, electronic organizers, e-books, PMPs, navigation, and UMPC.

In FIG. 1, a first direction DR1, a second direction DR2, and a third direction DR3 are defined. The first direction DR1 and the second direction DR2 may be perpendicular to each other, the first direction DR1 and the third direction DR3 may be perpendicular to each other, and the second direction DR2 and the third direction DR3 may be perpendicular to each other. It may be understood that the first direction DR1 means a vertical direction in the drawings, the second direction DR2 means a horizontal direction in the drawings, and the third direction DR3 means upper and lower directions in the drawings, e.g., a thickness direction.

In the following description, unless otherwise specified, the term “direction” may refer to both directions toward both sides extending along the direction. When both “directions” extending to both sides need to be distinguished from each other, a side will be referred to as “a side in the direction” and another side will be referred to as “another side in the direction”. In FIG. 1, a direction in which an arrow indicating a direction is directed is referred to as a side, and an opposite direction thereof is referred to as another side. However, it should be understood that the directions mentioned in the embodiments refer to relative directions, and the embodiments are not limited to the mentioned directions.

In referring to the surfaces of each member constituting the display device 1 without being bent with respect to the folding axis FX, a surface facing a side in a direction in which the image is displayed, e.g., the third direction DR3 is referred to as a top surface (or a upper surface), and an opposite surface of the surface is referred to as a bottom surface (or a lower surface). However, embodiments are not limited thereto, and a surface and another surface of the member may be referred to as a front surface and a bottom surface, respectively, or may also be referred to as a first surface or a second surface. In describing relative positions of the members of the display device 1, a side in the third direction DR3 may be referred to as an upper side and another side in the third direction DR3 may be referred to as a lower side.

A planar shape of the display device 1 may have a rectangular shape in which a vertical side is longer than a horizontal side as illustrated in FIG. 1, and each of the corner portions of the display device 1 may have a right-angled planar shape or a rounded planar shape, but embodiments are not limited thereto. For example, the planar shape of the display device 1 may have a rectangular shape in which the vertical side is shorter than the horizontal side. FIG. 1 illustrates a rectangular shape in which the vertical side is longer than the horizontal side.

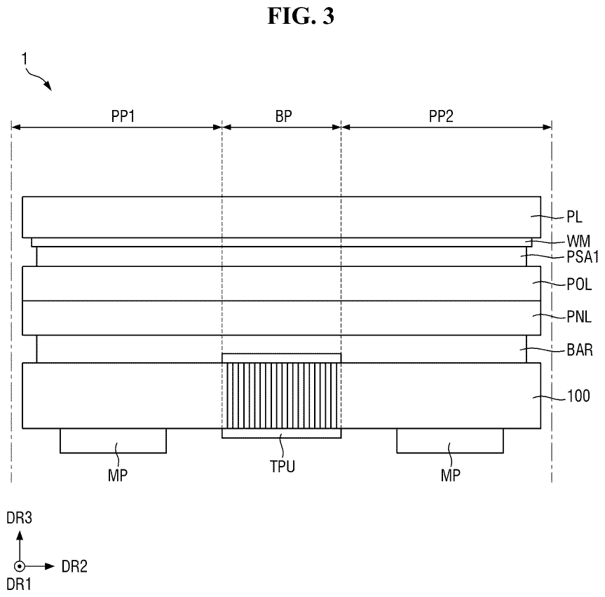

The display device 1 may include a first planarization portion PP1, a bending portion BP, and a second planarization portion PP2. The first planarization portion PP1, the bending portion BP and the second planarization portion PP2 defined in the display device 1 may also be applied to components of the display device 1 as illustrated in FIG. 3.

The first planarization portion PP1 and the second planarization portion PP2 may be portions that are not bent. The first planarization portion PP1 may be disposed on another side of the display device 1 in the second direction DR2 as a portion of the display device 1. The second planarization portion PP2 may be disposed on a side of the display device 1 in the second direction DR2 as a portion of the display device 2.

The bending portion BP may be disposed between the first planarization portion PP1 and the second planarization portion PP2. For example, the second planarization portion PP2 may be disposed on a side of the bending portion BP in the second direction DR2, and the first planarization portion PP1 may be disposed on another side of the bending portion BP in the second direction DR2. A first bending line BL1 may be a boundary between the bending portion BP and the first planarization portion PP1, and the second bending line BL2 may be a boundary between the bending portion BP and the second planarization portion PP2.

The bending portion BP may be a bendable area. For example, the bending portion BP may be bent with respect to the folding axis FX disposed on the bending portion BP and extending in the first direction DR1. In case that the bending portion BP is not bent, the display device 1 may maintain an unfolded state (hereinafter, referred to as a ‘first state’) as illustrated in FIG. 1, and in case that the bending portion BP is bent, the display device 1 may maintain a folded state (hereinafter, referred to as a ‘second state’) as illustrated in FIG. 2.

The display device 1 may include a display area and a non-display area.

The display area may be an area in which pixels are disposed to display a screen. The display area may include a first display area DA1 and a second display area DA2. The non-display area may be an area that does not display a screen. The non-display area may include a first non-display area NDA1 and a second non-display area NDA2.

In the first state of the display device 1, a side surface of the display device 1 in the third direction DR3 may be a front surface on which the first display area DA1 and the first non-display area NDA1 are disposed, and another surface of the display device 1 in the third direction DR3 may be a bottom surface on which the second display area DA2 and the second non-display area NDA2 are disposed.

The first display area DA1 may be disposed on a surface of the display device 1 in the third direction DR3 in the first state of the display device 1. A planar shape of the first display area DA1 may have a planar shape of the display device 1 in the first state. For example, in case that the planar shape of the display device 1 in the first state is a rectangle, the planar shape of the first display area DA1 may also be a rectangle.

In some embodiments, the first display area DA1 may be surrounded by the first non-display area NDA1, but embodiments are not limited thereto. For example, the first display area DA1 may be partially surrounded by the first non-display area NDA1. FIG. 1 illustrates that the first non-display area NDA1 surrounds the first display area DA1.

The second display area DA2 may be disposed on another surface of the display device 1 in the third direction DR3 in the first state of the display device 1, and may overlap only the first planarization portion PP1, but embodiments are not limited thereto. The second display area DA2 may display a screen to the user in case that the display device 1 is in the second state.

The second display area DA2 may have a planar shape of the first planarization portion PP1 visually recognized by the user in the display device 1 in the second state as illustrated in FIG. 2. For example, in case that the planar shape of the first planarization portion PP1 visually recognized by the user in the display device 1 in the second state is a rectangle, a planar shape of the second display area DA2 may also be a rectangle.

In some embodiments, the second display area DA2 may be surrounded by the second non-display area NDA2, but embodiments are not limited thereto. For example, the second display area DA2 may be partially surrounded by the second non-display area NDA2.

As illustrated in FIG. 2, the display device 1 may be folded in an in-folding manner in which a portion of the first display area DA1 disposed on the first planarization portion PP1 and a portion of the first display area DA1 disposed on the second planarization portion PP2 are folded to face each other in the second state thereof, but embodiments are not limited thereto. For example, the display device 1 may be folded in an out-folding manner so that the bottom surfaces thereof face each other. FIG. 2 illustrates that the display device 1 is folded in an in-folding manner.

Hereinafter, a structure of the display device 1 will be described.

FIG. 3 is a schematic side view illustrating a structure of the display device according to an embodiment.

Referring to FIG. 3, the display device 1 according to an embodiment may include an upper protective member PL, a window member WM, a first adhesive member PSA1, a polarizing member POL, a display panel PNL, a barrier member BAR, a panel supporter 100, a lower visibility preventing member TPU, and a metal supporter MP.

The upper protective member PL may function to perform at least one of scattering prevention, shock absorption, engraving prevention, fingerprint prevention, and glare prevention of the window member WM, which will be described below. The upper protective member PL may be disposed on a surface (hereinafter, referred to as a ‘front surface’) of the window member WM in the third direction DR3. The upper protective member PL may be attached to a front surface of the window member through an adhesive member such as a pressure-sensitive adhesive.

A light blocking pattern may be formed on a surface (hereinafter, referred to as a ‘bottom surface’ or a ‘lower surface’) of the upper protective member PL in the third direction DR3. The light blocking pattern may be disposed at an edge portion of the upper protective member PL or adjacent to the edge portion. The light blocking pattern may include a light blocking material capable of blocking light. For example, the light blocking pattern may be an inorganic black pigment such as carbon black, an organic black pigment, or an opaque metal material.

The window member WM may function to protect the display panel PNL, which will be described below, from the outside. The window member WM may be disposed on a side surface (hereinafter, referred to as a ‘front surface’) of the display panel PNL in the third direction DR3. The window member WM may be made of a transparent material, for example, glass or plastic.

The window member WM may be an ultra-thin glass having a thickness of about 0.1 mm or less or a transparent polyimide film. The window member WM may be attached to a front surface of the polarizing member POL by the first adhesive member PSA1. The first adhesive member PSA1 may be a transparent adhesive film or a transparent adhesive resin.

The polarizing member POL may prevent external light incident on the display panel PNL from being reflected. The polarizing member POL may be attached to the window member WM through the first adhesive member PSA1 as a medium. A display panel PNL may be disposed on a bottom surface of the polarizing member POL.

The display panel PNL may be a panel that displays a screen, and any type of display panel such as an organic light emitting display panel including an organic light emitting layer, a micro light emitting diode (LED) display panel including a micro light emitting diode, a quantum dot light emitting display panel including a quantum dot light emitting diode including a quantum dot light emitting layer, and an inorganic light emitting display panel including an inorganic light emitting element including an inorganic semiconductor may be applied as the display panel PNL according to an embodiment. Referring to FIG. 1, the display panel PNL may display a screen on a side thereof in the third direction DR3.

The barrier member BAR may be disposed on a side surface (hereinafter, referred to as a ‘bottom surface’ or a ‘lower surface’) of the display panel PNL in the third direction DR3. A portion overlapping the bending portion BP among side surfaces of the barrier member BAR in the third direction DR3 may be spaced apart from a grid pattern disposed on the bending portion BP of the panel supporter 100 to be described below in the third direction DR3.

The barrier member BAR may include at least one of a light blocking layer that absorbs light incident from the outside, a buffer layer that absorbs a shock from the outside, and a heat dissipation layer that efficiently dissipate heat of the display panel PNL.

The light blocking layer may block transmission of light and may prevent components disposed on a lower side of the light blocking layer from being visually viewed (or recognized) from the front surface of the display panel PNL. The light blocking layer may include a light absorbing material such as a black pigment or a black dye.

The buffer layer may absorb the external shock to prevent the display panel PNL from being damaged. The buffer layer may be formed as a single layer or a plurality of layers. For example, the buffer layer may be formed of a polymer resin such as polyurethane, polycarbonate, polypropylene, or polyethylene or may include a material having elasticity, such as a sponge formed by foaming rubber, a urethane-based material, or an acrylic-based material.

The heat dissipation layer may include a first heat dissipation layer including graphite or carbon nano-tube, and a second heat dissipation layer formed of a thin metal film such as copper, nickel, ferrite, or silver that shield electromagnetic waves and have excellent thermal conductivity.

The panel supporter 100 may function to support the bottom surface of the display panel PNL. The panel supporter 100 may be disposed on a surface (hereinafter, referred to as a ‘bottom surface’ or ‘lower surface’) of the barrier member BAR in the third direction DR3. The panel supporter 100 may be a rigid member whose shape or volume is not readily changed by external pressure. A grid pattern for readily bending the panel supporter 100 may be formed on the bending portion BP of the panel supporter 100.

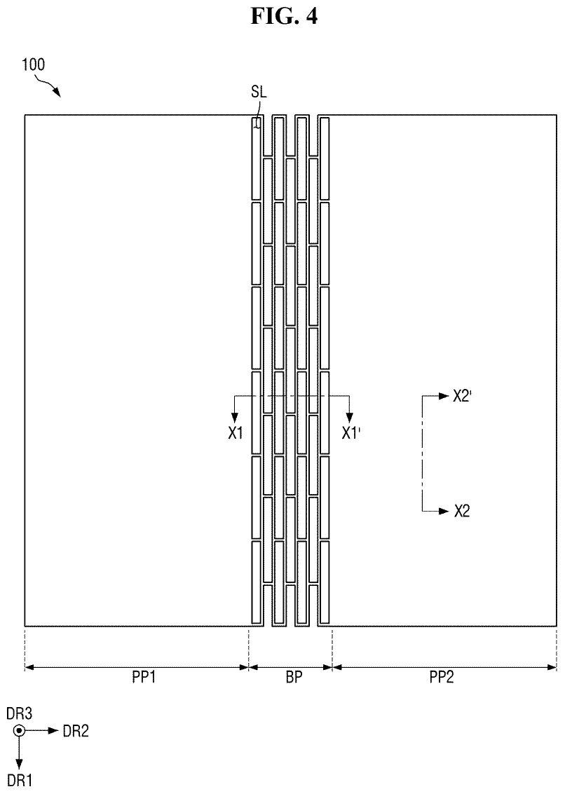

In some embodiments, the panel supporter 100 may be carbon fiber reinforced plastic (CFRP) including carbon fibers, but embodiments are not limited thereto. For example, the panel supporter 100 may also be glass fiber reinforced plastic (GFRP) including glass fibers, or aramid fiber reinforced plastic (AFRP). Hereinafter, it will be described that the panel supporter 100 is carbon fiber reinforced plastic. The structure of the panel supporter 100 will be described below in detail with reference to FIGS. 4, 5, and 6.

The lower visibility preventing member TPU may be disposed on a bottom surface of the grid pattern formed on the bending portion BP of the panel supporter 100. The lower visibility preventing member TPU may prevent the grid pattern of the panel supporter 100 from being visually recognized to the outside. The lower visibility preventing member TPU may include a flexible material to reduce folding stress of the display device 1.

The metal supporter MP may be disposed on a bottom surface (or a lower surface) of each of the first planarization portion PP1 and the second planarization portion PP2 of the panel supporter 100. The metal supporter MP may function to support the bottom surface of each of the first planarization portion PP1 and the second planarization portion PP2 of the panel supporter 100 and absorb heat generated from the display panel PNL. In some embodiments, the metal supporter MP may include copper (Cu), but embodiments are not limited thereto. The metal supporter MP may not be disposed on the bending portion BP to reduce the folding stress of the display device 1.

Hereinafter, a structure of the panel supporter 100 of the display device 1 according to an embodiment will be described with reference to FIGS. 4 to 10.

FIG. 4 is a schematic plan view illustrating a panel supporter of the display device according to an embodiment.

Referring to FIG. 4, the panel supporter 100 of the display device 1 according to an embodiment may include a first planarization portion PP1, a bending portion BP, and a second planarization portion PP2.

The first planarization portion PP1 and the second planarization portion PP2 of the panel supporter 100 may be portions that are not bent. The first planarization portion PP1 may be disposed on another side (or a left side) of the panel supporter 100 in the second direction DR2 as a portion of the panel supporter 100. The second planarization portion PP2 may be disposed on a side (or a right side) of the panel supporter 100 in the second direction DR2 as a portion of the panel supporter 100.

The bending portion BP of the panel supporter 100 may be disposed between the first planarization portion PP1 and the second planarization portion PP2. For example, the second planarization portion PP2 may be disposed on a side (or a right side) of the bending portion BP in the second direction DR2, and the first planarization portion PP1 may be disposed on another side (or a left side) of the bending portion BP in the second direction DR2.

The bending portion BP of the panel supporter 100 may be a bendable area. A grid pattern including slits SL penetrating through the panel supporter 100 in the third direction DR3 may be formed on the bending portion BP. The slits SL may include columns arranged in the first direction DR1, and may have a shape in which each column is arranged in the second direction DR2. Accordingly, the bending portion BP of the panel supporter 100 may be readily bent.

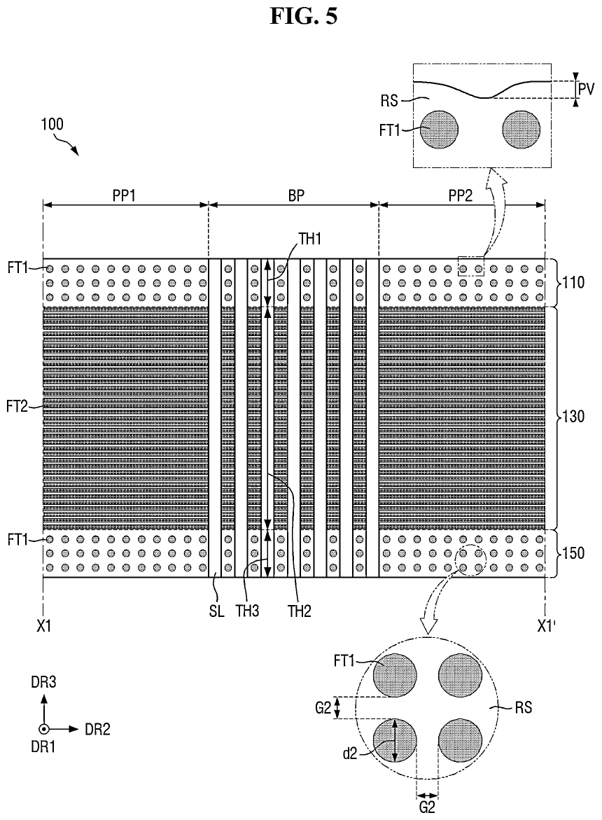

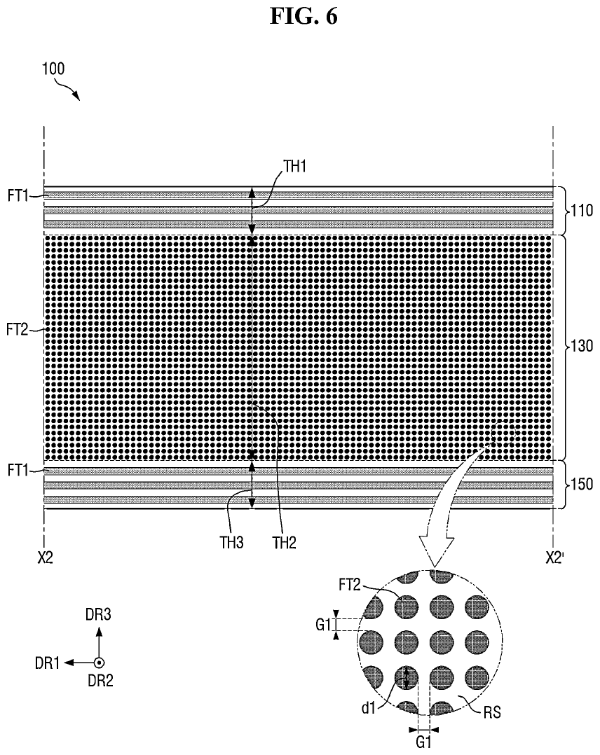

FIG. 5 is a schematic cross-sectional view illustrating a cross section taken along line X1-X1′ of FIG. 4. FIG. 6 is a schematic cross-sectional view illustrating a cross section taken along line X2-X2′ of FIG. 4.

Referring to FIGS. 5 and 6 together with FIG. 4, the panel supporter 100 may be fiber reinforced plastic including fiber yarns and a base resin RS. The fiber yarns may be dispersed in the base resin RS. The fiber yarn may include graphene as a carbon fiber including carbon, and the base resin RS may be an epoxy-based resin, a polyester-based resin, a polyamide-based resin, a polycarbonate-based resin, a polypropylene-based resin, a polybutylene-based resin, a polyacrylate-based resin, or a vinyl ester-based resin.

The panel supporter 100 may include the first layer 110, the second layer 130, and the third layer 150 sequentially arranged in the third direction DR3. For example, the first layer 110 of the panel supporter 100 may be adjacent to the barrier member BAR disposed on an upper side of the panel supporter 100, and the third layer 150 of the panel supporter 100 may be adjacent to the lower visibility preventing member TPU and the metal supporter MP disposed on a lower side of the panel supporter 100.

The base resin RS may be integrally disposed (or formed) in all of the first layer 110, the second layer 130, and the third layer 150 of the panel supporter 100. In the description, a portion of the base resin RS disposed in the first layer 110 may be referred to as a first base resin, a portion of the base resin RS disposed in the second layer 130 may be referred to as a second base resin, and a portion of the base resin RS disposed in the third layer 150 may be referred to as a third base resin.

The fiber yarns may include first fiber yarns FT1 and second fiber yarns FT2 having different diameters, different elastic moduli, or different carbon contents. The first fiber yarns FT1 may be disposed in the first layer 110 and the third layer 150 of the panel supporter 100, and the second fiber yarns FT2 may be disposed in the second layer 130 of the panel supporter 100. For example, the same type of fiber yarn as the first fiber yarns FT1 may be disposed in the first layer 110 and the third layer 150. The different type of fiber yarns (e.g., the second fiber yarn FT2) from the fiber yarn, which is disposed in the first layer 110 and the third layer 150, may be disposed in the second layer 130.

For example, the first layer 110 may be a prepreg including the first fiber yarns FT1 extending substantially in parallel in the first direction DR1 and a portion of the base resin RS surrounding the first fiber yarns FT1. The second layer 130 may be a prepreg including the second fiber yarns FT2 extending substantially in parallel in the second direction DR2 and a portion of the base resin RS surrounding the second fiber yarns FT2. For example, the the first fiber yarns FT1 and the second fiber yarns FT2 may have different types of fiber yarns from each other. The third layer 150 may be a prepreg including the first fiber yarns FT1 extending substantially in parallel in the first direction DR1 and a portion of the base resin RS surrounding the first fiber yarns FT1.

In the description, the meaning of ‘extending substantially in parallel in the first direction DR1’ includes extending to be parallel to the first direction DR1 or extending to have an angle of intersection of about 15° or less by slightly intersecting the second direction DR2. The meaning of ‘extending substantially in parallel in the second direction DR2’ includes extending to be parallel to the second direction DR2 or extending to have an angle of intersection of about 15° or less by slightly intersecting the first direction DR1.

The extending direction of the first fiber yarns FT1 disposed in the first layer 110 and the third layer 150 may extend substantially in parallel in the first direction DR1, and the first direction DR1 may be a direction parallel to the folding axis FX illustrated in FIGS. 1 and 2. Therefore, the first layer 110 and the third layer 150 may be readily folded in case that the display device 1 is switched from the first state to the second state. However, in case that the panel supporter 100 includes only the first fiber yarns FT1, the panel supporter 100 may be curved or bent in the first direction DR1. For example, in case that the panel supporter 100 includes only the first fiber yarns FT1, flatness and rigidity of the panel supporter 100 may be low.

Accordingly, as the panel supporter 100 further includes the second layer 130 having the second fiber yarns FT2 extending substantially in the second direction DR2, the panel supporter 100 may be prevented from being curved or bent in the first direction DR1 such that the rigidity of the panel supporter 100 may increase.

However, in consideration of the rigidity required for the panel supporter 100, the content (or amount) of the second fiber yarns FT2 of the panel supporter 100 may be greater than the content (or amount) of the first fiber yarns FT1. For example, a thickness TH2 of the second layer 130 of the panel supporter 100 in the third direction DR3 may be greater than a thickness TH1 of the first layer 110 in the third direction DR3 and a thickness TH3 of the third layer 150 in the third direction DR3. The thickness TH1 of the first layer 110 in the third direction DR3 and the thickness TH3 of the third layer 150 in the third direction DR3 may be the same as each other. In some embodiments, the thickness TH1 of the first layer 110 and the thickness TH3 of the third layer 150 may be about 20 μm, and the thickness TH2 of the second layer 130 may be about 100 μm, but embodiments are not limited thereto.

As the fiber yarns extending in a direction are disposed in each layer as described above, the thickness of each layer itself may not be increased. In a comparative example, in case that both the first fiber yarns FT1 and the second fiber yarns FT2 are disposed in any one layer of the panel supporter 100, portions at which the first fiber yarns FT1 and the second fiber yarns FT2 intersect may be formed, thereby increasing the thickness of the layer itself. Therefore, by disposing the fiber yarns extending only in a direction in each layer, the rigidity required for the panel supporter 100 may be secured and may minimize the thickness of the layer itself.

The first fiber yarn FT1 and the second fiber yarn FT2 may be made of carbon fiber and may have a cylindrical shape having a circular cross-section. A diameter d2 of the first fiber yarn FT1 may be greater than a diameter d1 of the second fiber yarn FT2. For example, the diameter d2 of the first fiber yarn FT1 may be in a range of about 6.5 μm or more and about 7.5 μm or less, and the diameter d1 of the second fiber yarn FT2 may be in a range of about 4.5 μm or more and about 5.5 μm or less. Accordingly, the number per unit volume of the first fiber yarns FT1 disposed in the first layer 110 and the third layer 150 may be smaller than the number per unit volume of the second fiber yarns FT2 disposed in the second layer 130. For example, comparing FIGS. 5 and 6, the number of the fiber yarns disposed on the same area (or the unit area) may be greater in the second layer 130 than in the first layer 110 or the third layer 150. For example, a gap G1 at which the second fiber yarns FT2 are spaced apart from each other in the second layer 130 may be smaller than a gap G2 at which the first fiber yarns FT1 are spaced apart from each other in the first layer 110 or the third layer 150.

As the first layer 110 and the third layer 150 include the same type of fiber yarn, each layer of the panel supporter 100 may be manufactured without misalignment in a process of manufacturing the panel supporter 100 to be described below.

Since the second layer 130 is stronger than the first layer 110 and the third layer 150 by the configuration as described above, visual recognition of the first fiber yarns FT1 disposed in the first layer 110 and the third layer 150 to the outside may be reduced or minimized.

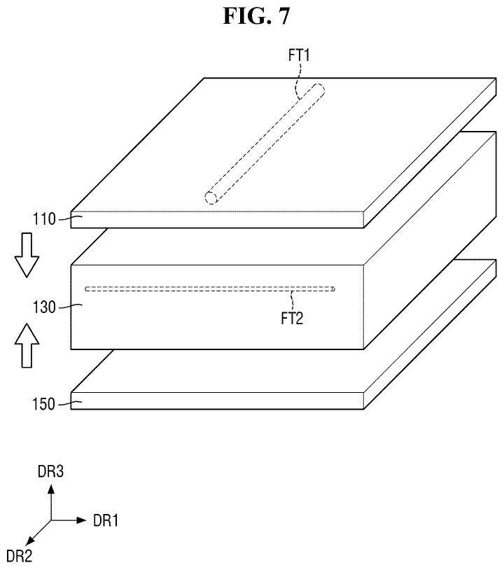

For example, as the base resin RS of the first layer 110 and the third layer 150 is thermally contracted in a process of stacking the first layer 110, the second layer 130, and the third layer 150 as described below, the surfaces of the first layer 110 and the third layer 150 have a bent shape, and a surface step PV as illustrated in FIG. 5 may be formed. The surface step PV may refer to a gap between a downwardly concave point and an upwardly convex point on the bent surface. Since the surface step PV is formed between the first fiber yarns FT1 disposed in the first layer 110 or the third layer 150, the surface step PV may generally have a shape extending in the first direction DR1. A detailed description thereof will be described with reference to FIGS. 7 to 14.

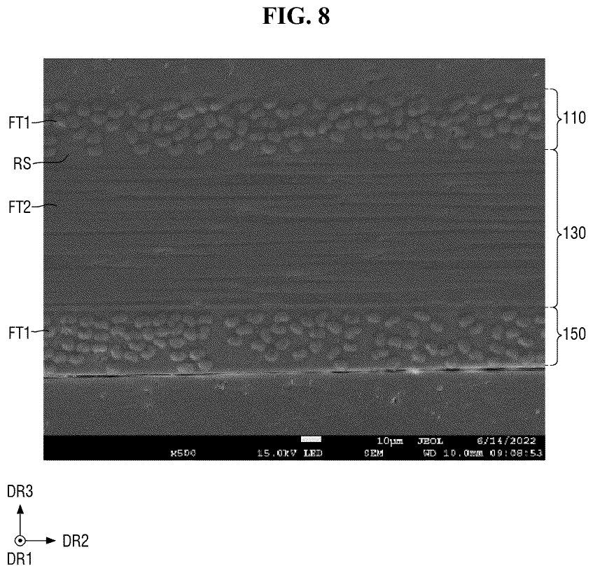

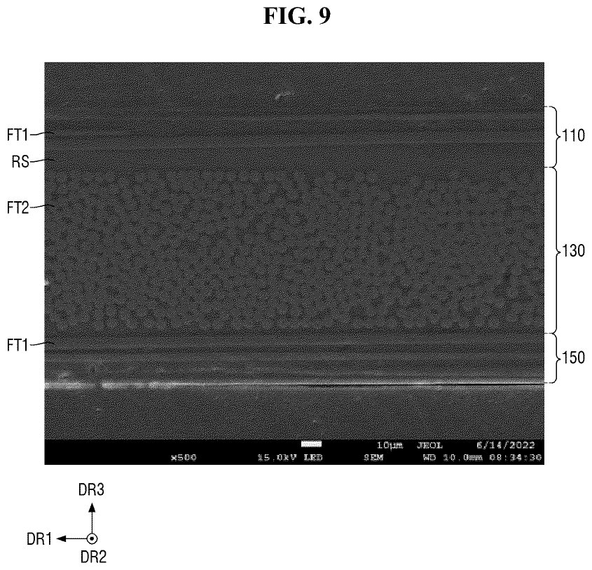

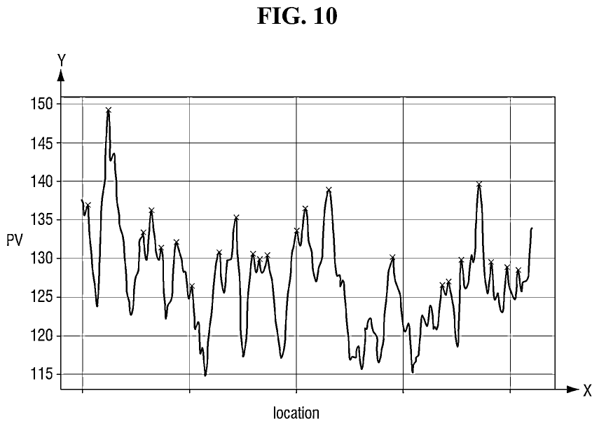

FIG. 7 is a schematic view for describing a process of manufacturing the panel supporter of the display device according to an embodiment. FIG. 8 is an image obtained by photographing a cross-section of the panel supporter of the display device according to an embodiment, viewed from a first direction DR1. FIG. 9 is an image obtained by photographing a cross-section of the panel supporter of the display device according to an embodiment, viewed from a second direction DR2. FIG. 10 is a graph illustrating a surface step for each position of the panel supporter of the display device according to an embodiment.

Referring to FIG. 7, the first layer 110, the second layer 130, and the third layer 150 of the panel supporter 100 may be stacked by hot press or autoclave. For example, the base resin RS disposed in the first layer 110, the second layer 130, and the third layer 150 may be melted in the process of stacking the first layer 110, the second layer 130, and the third layer 150 and may permeate into a spaced space between the filer yarns of each layer.

For example, as illustrated in FIGS. 8 and 9, the base resin RS included in the first layer 110 and the third layer 150 is melted in the stacking process and permeates into the spaced space between the second fiber yarns FT2 disposed in the second layer 130, so that the surfaces of the first layer 110 and the third layer 150 may have a bent shape.

Accordingly, since the amount of the base resin RS of the first layer 110 and the third layer 150 permeating into the spaced space between the second fiber yarns FT2 disposed in the second layer 130 in the process of stacking each layer of the panel supporter 100 may be reduced by increasing the number per unit volume of the second fiber yarns FT2 disposed in the second layer 130 to narrow the spaced space between the second fiber yarns FT2, the degree of curvature of the surfaces of the first layer 110 and the third layer 150 may be reduced.

Referring to FIG. 10, a surface step PV for each position of the panel supporter 100 as viewed in the second direction DR2 is illustrated. A Y axis of the graph illustrated in FIG. 10 represents the relative degree (e.g., dimensionless) of the surface step PV, and an X axis represents a position in the second direction DR2. The surface step PV for each position of the panel supporter 100 is measured in case that the first fiber yarn FT1 is T700 carbon fiber (as TORAYCA™ carbon fiber), which is manufactured by Toray, and the second fiber yarn FT2 is T800 carbon fiber (as TORAYCA™ carbon fiber), which is manufactured by Toray, as illustrated in the graph of FIG. 10 through repeated experiments.

T700 carbon fiber, which is manufactured by Toray, may have a diameter in the range of about 6.5 μm or more to about 7.5 μm or less, may have a modulus of about 240 GPa, and may have a carbon content of about 93% or less. T800 carbon fiber, which is manufactured by Toray may have a diameter in the range of about 4.5 μm or more to about 5.5 μm or less, may have a modulus of about 294 GPa, and may have a carbon content of about 96% or less. For example, the surface step PV of the panel supporter 100 of the display device 1 according to an embodiment may have a relative degree of about 148.5 as the maximum value to about 115 as the minimum value. The modulus refers to a modulus of elasticity (e.g., Young's modulus or elastic modulus) for tensile in the case of fibers.

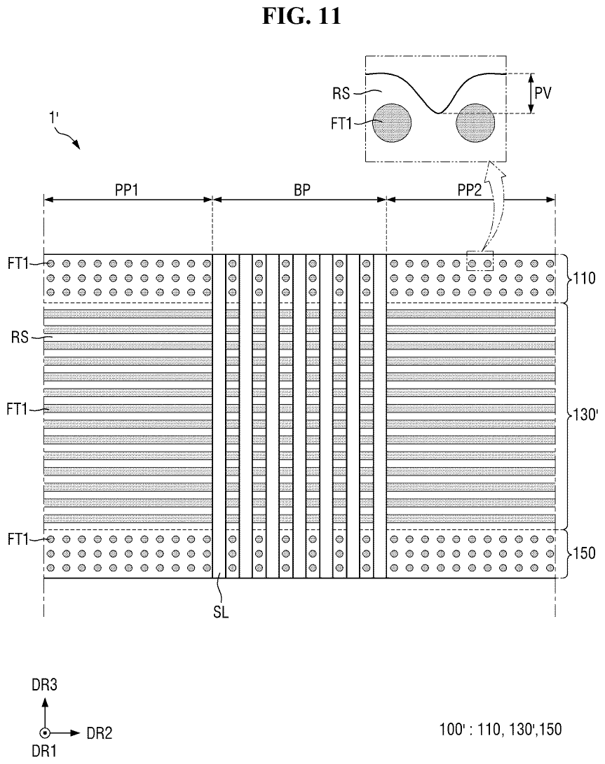

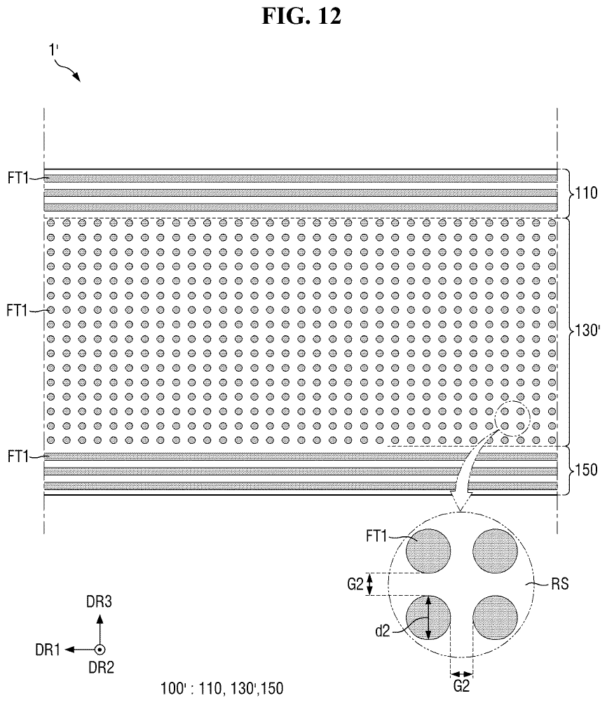

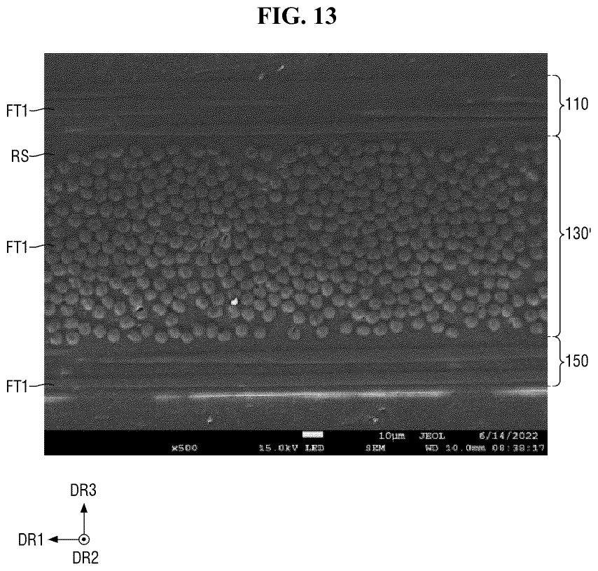

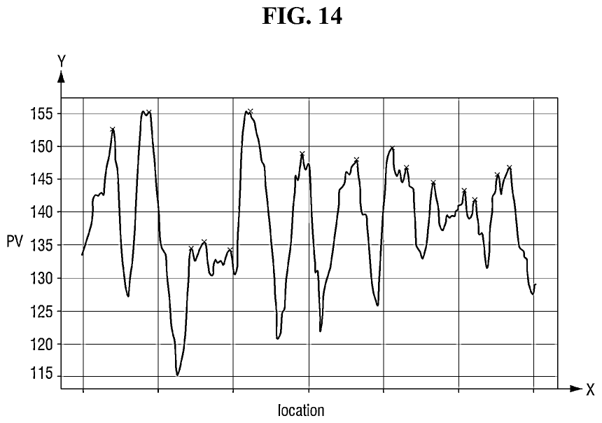

FIG. 11 is a schematic cross-sectional view illustrating a structure of a panel supporter of a display device according to a comparative example. FIG. 12 is a schematic cross-sectional view illustrating a structure of a panel supporter of a display device according to a comparative example. FIG. 13 is an image obtained by photographing a cross-section of the panel supporter of the display device according to an embodiment, viewed from a second direction. FIG. 14 is a graph illustrating a surface step for each position of a panel supporter of a display device according to an embodiment.

Referring to FIGS. 11 to 14, a panel supporter 100′ of a display device 1′ according to a comparative example is different from the panel supporter 100 of the display device 1 according to an embodiment in that a second layer 130′ of the panel supporter 100′ includes the first fiber yarns FT1 as the fiber yarns, and other configurations are substantially the same or similar. For example, the first layer 110, the second layer 130′, and the third layer 150 may have the same type of fiber yarn, and the number of the fiber yarns per unit volume of the first layer 110, the second layer 130′, and the third layer 150 may also be the same as each other.

For example, a surface step PV formed on the surface of the first layer 110 of the display device 1′ according to the comparative example illustrated in FIG. 12 may be greater than the surface step PV formed on the surface of the first layer 110 of the display device 1 according to an embodiment illustrated in FIG. 6. For example, as illustrated in FIGS. 11 to 13, a diameter of the first fiber yarn FT1 as the fiber yarn disposed in the second layer 130′ is greater than the diameter of the second fiber yarn FT2 disposed in the second layer 130 of the panel supporter 100 according to an embodiment. Thus, the number of the fiber yarns disposed per unit volume of the second layer 130′ in the comparative example may be reduced, and a spaced distance between the fiber yarns of the second layer 130′ may be increased. Accordingly, an amount of the base resin RS of the first layer 110 and the third layer 150 permeating into the second layer 130′ may be increased in the stacking process as described above in FIG. 7.

Referring to FIG. 14, a surface step PV for each position of the panel supporter 100′ as viewed in the second direction DR2 is illustrated. A Y axis of the graph illustrated in FIG. 14 represents the relative degree (e.g., dimensionless) of the surface step PV, and an X axis represents a position in the second direction DR2. The surface step PV for each position of the panel supporter 100 is measured in case that the first fiber yarn FT1 is T700 carbon fiber, which is manufactured by Toray, as illustrated in the graph of FIG. 14 through repeated experiments.

For example, the surface step PV of the panel supporter 100′ of the display device 1′ according to the comparative example may have a relative degree of about 155.4 as the maximum value to about 115 as the minimum value.

Referring to FIGS. 10 to 14, the surface step PV of the panel supporter 100 of the display device 1 according to an embodiment has the relative degree of about 148.5 as the maximum value to about 115 as the minimum value, and the surface step PV of the panel supporter 100′ of the display device 1′ according to the comparative example has the relative degree of about 155.4 as the maximum value to about 115 as the minimum value. Thus, the surface step PV of the panel supporter 100 of the display device 1 according to an embodiment may be reduced as compared to the surface step PV of the panel supporter 100′ of the display device 1′ according to the comparative example.

Hereinafter, other embodiments of the display device 1 will be described. In the following embodiments, the same components as those of the above-described embodiment will be denoted by the same reference numerals, and a redundant description thereof will be omitted or simplified and differences will be described for descriptive convenience.

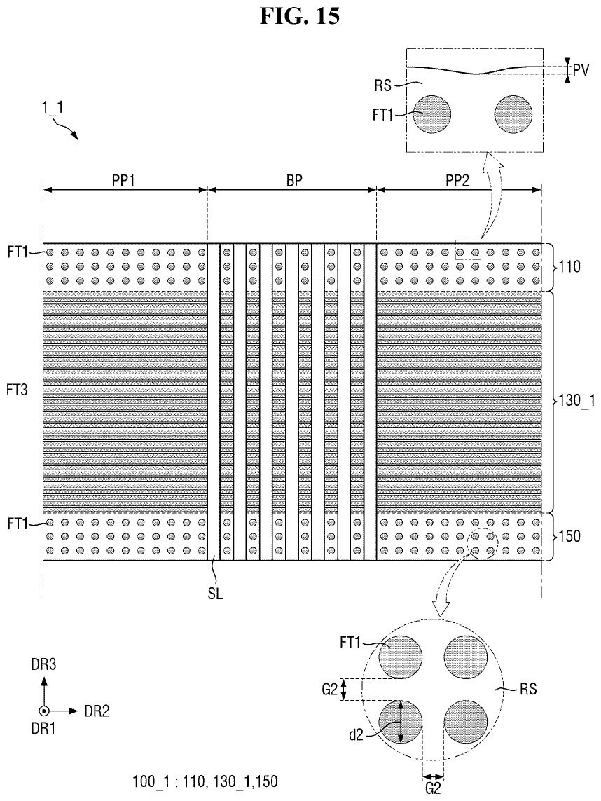

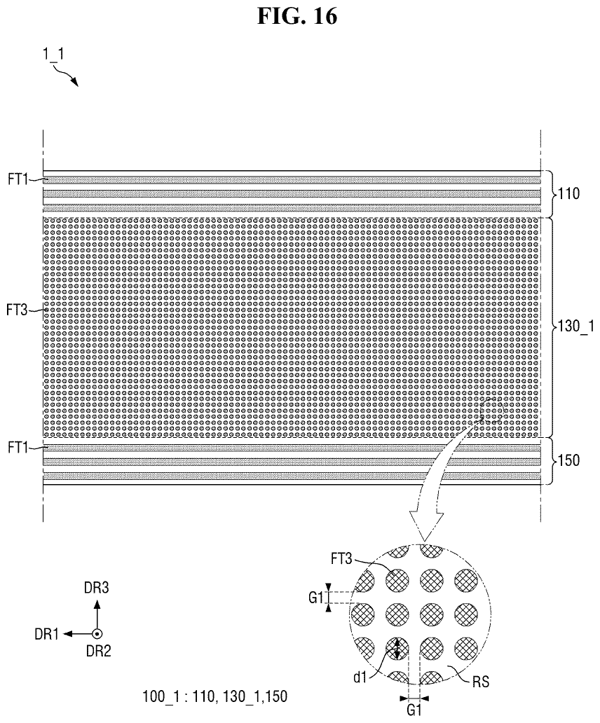

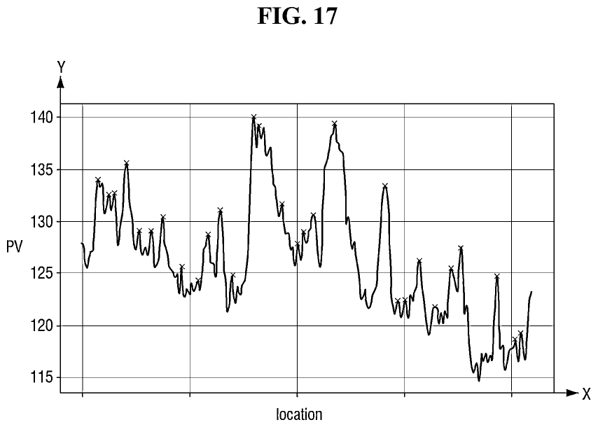

FIG. 15 is a schematic cross-sectional view illustrating a structure of a panel supporter of a display device according to another embodiment. FIG. 16 is a schematic cross-sectional view illustrating a structure of the panel supporter of the display device according to the embodiment of FIG. 15. FIG. 17 is a graph illustrating a surface step for each position of the panel supporter of the display device according to the embodiment of FIG. 15.

Referring to FIGS. 15 and 16, a panel supporter 100_1 of a display device 1_1 according to the embodiment of FIGS. 15 and 16 is different from the panel supporter 100 of the display device 1 according to the embodiment of FIGS. 5 and 6 in that an elastic modulus of the fiber yarn disposed in a second layer 130_1 of the panel supporter 100_1 is greater than an elastic modulus of the fiber yarn disposed in the second layer 130 of the panel supporter 100, and other configurations are substantially same or similar.

For example, the elastic modulus of the third fiber yarn FT3 disposed in the second layer 130_1 of the display device 1_1 according to the embodiment of FIGS. 15 and 16 may be greater than the elastic modulus of the second fiber yarn FT2 disposed in the second layer 130 of the display device 1 according to the embodiment of FIGS. 5 and 6. The diameter d1 of the third fiber yarn FT3 of FIGS. 15 and 16 may be in the range of about 4.5 μm or more and about 5.5 μm or less. The diameter d1 of the third fiber yarn FT3 of the embodiment of FIGS. 15 and 16 and the diameter d1 of the second fiber yarn FT2 of the embodiment of FIGS. 5 and 6 may be substantially the same as each other. A gap G1 at which the third fiber yarns FT3 are spaced apart from each other in the second layer 130_1 may be smaller than the gap G2 at which the first fiber yarns FT1 are spaced apart from each other in the first layer 110 or the third layer 150 (see, e.g., FIGS. 15 and 16).

The elastic modulus of the third fiber yarn FT3 may be greater than the elastic modulus of the first fiber yarn FT1. In case that the fiber yarn includes carbon fibers, there may be a correlation that the elastic modulus may increase as the carbon content increases. Accordingly, the carbon content of the third fiber yarn FT3 may be greater than the carbon content of the first fiber yarn FT1. In some embodiments, the elastic modulus of the third fiber yarn FT3 may be about 377 GPa or more, and the elastic modulus of the first fiber yarn FT1 may be about 240 GPa or less, and the carbon content of the third fiber yarn FT3 may be about 99% or more, and the carbon content of the first fiber yarn FT1 may be about 93% or less, but embodiments are not limited thereto.

Since the second layer 130_1 of the panel supporter 100_1 includes the fiber yarn having a higher elastic modulus than that of the first layer 110 and the third layer 150 as described above, the second layer 130_1 may have stronger rigidity than that of the first and third layers 110 and 150. Accordingly, visual recognition of the first fiber yarns FT1 disposed in the first layer 110 and the third layer 150 to the outside may be reduced or minimized.

For example, as described above with reference to FIG. 7, as the base resin RS of the first layer 110 and the third layer 150 is thermally contracted in the process of stacking the first layer 110, the second layer 130, and the third layer 150, the surfaces of the first layer 110 and the third layer 150 may have the bent shape. For example, in case that the second layer 130_1 has the stronger rigidity than that of the first layer 110 and the third layer 150, the surface step PV generated by the thermal contraction may be reduced by reducing the degree of thermal contraction of the base resin RS of the first layer 110 and the third layer 150.

For example, the surface step PV formed in the panel supporter 100_1 of the display device 1_1 according to the embodiment of FIGS. 15 and 16 may be smaller than the surface step PV formed in the panel supporter 100 of the display device 1 according to the embodiment of FIGS. 5 and 6. This is because the third fiber yarn FT3 of the display device 1_1 according to the embodiment of FIGS. 15 and 16 has the greater elastic modulus than the elastic modulus that of the second fiber yarn FT2 of the display device 1 according to the embodiment of FIGS. 5 and 6.

Referring to FIG. 17, a surface step PV for each position of the panel supporter 100_1 as viewed in the second direction DR2 is illustrated. A Y axis of the graph illustrated in FIG. 17 represents the relative degree (e.g., dimensionless) of the surface step PV, and an X axis represents a position in the second direction DR2. The inventors of the present specification measured the surface step PV for each position of the panel supporter 100_1 in which the first fiber yarn FT1 is T700 carbon fiber, which is manufactured by Toray, and the third fiber yarn FT3 is M40 carbon fiber (as TORAYCA™ carbon fiber), which is manufactured by Toray, as illustrated in the graph of FIG. 17 through repeated experiments.

The T700 carbon fiber, which is manufactured by Toray, may have a diameter in the range of about 6.5 μm or more to about 7.5 μm or less, may have an elastic modulus of about 240 GPa, and may have a carbon content of about 93% or less. The M40 carbon fiber, which is manufactured by Toray, may have a diameter in the range of about 4.5 μm or more and about 5.5 μm or less, may have an elastic modulus of about 377 GPa, and may have a carbon content of about 99% or less. For example, the surface step PV of the panel supporter 100_1 of the display device 1_1 according to the embodiment of FIGS. 15 and 16 may have a relative degree of about 140.1 as the maximum value to about 115 as the minimum value.

Referring to FIGS. 10 to 17, since the surface step PV of the panel supporter 100 of the display device 1 according to the embodiment of FIGS. 5 and 6 has the relative degree of about 148.5 as the maximum value to about 115 as the minimum value, and the surface step PV of the panel supporter 100_1 of the display device 1_1 according to the embodiment of FIGS. 15 and 16 has the relative degree of about 140.1 as the maximum value to about 115 as the minimum value, the surface step PV of the panel supporter 100_1 of the display device 1_1 according to the embodiment of FIGS. 15 and 16 may be reduced as compared to the surface step PV of the panel supporter 100 of the display device 1 according to the embodiment of FIGS. 5 and 6.

The above description is an example of technical features of the disclosure, and those skilled in the art to which the disclosure pertains will be able to make various modifications and variations. Therefore, the embodiments of the disclosure described above may be implemented separately or in combination with each other.

In concluding the detailed description, those skilled in the art will appreciate that many variations and modifications may be made to the embodiments without substantially departing from the principles and spirit and scope of the disclosure. Therefore, the disclosed embodiments are used in a generic and descriptive sense only and not for purposes of limitation.

What is claimed is:

1. A display device comprising:
a display panel having a folding axis extending in a first direction; and
a panel supporter disposed on a surface of the display panel, wherein
the panel supporter includes:
a first layer including a first base resin and first fiber yarns, the first fiber yarns extending in the first direction and dispersed in the first base resin;
a second layer disposed on the first layer, the second layer including a second base resin and second fiber yarns, the second fiber yarns extending in a second direction intersecting the first direction and dispersed in the second base resin; and
a third layer disposed on the second layer, the third layer including a third base resin and third fiber yarns, the third fiber yarns extending in the first direction and dispersed in the third base resin, and
the number of the second fiber yarns per unit volume of the second layer is greater than the number of the first fiber yarns per unit volume of the first layer and the number of the third fiber yarns per unit volume of the third layer.

2. The display device of claim 1, wherein a diameter of each of the second fiber yarns is smaller than a diameter of each of the first fiber yarns and a diameter of each of the third fiber yarns.

3. The display device of claim 2, wherein the diameter of each of the first fiber yarns and the diameter of each of the third fiber yarns are same as each other.

4. The display device of claim 3, wherein a spaced distance between the second fiber yarns in the second layer is smaller than a spaced distance between the first fiber yarns in the first layer and a spaced distance between the third fiber yarns in the third layer.

5. The display device of claim 4, wherein
the diameter of each of the second fiber yarns is about 4.5 μm or more and about 5.5 μm or less, and
the diameter of each of the first fiber yarns and the diameter of each of the third fiber yarns are about 6.5 μm or more and about 7.5 μm or less.

6. The display device of claim 1, wherein a thickness of the second layer is greater than a thickness of the first layer and a thickness of the third layer.

7. The display device of claim 6, wherein the second layer is disposed between the first layer and the third layer.

8. The display device of claim 7, wherein the thickness of the first layer and the thickness of the third layer are same as each other.

9. The display device of claim 1, wherein
the first fiber yarns, the second fiber yarns and the third fiber yarns include carbon, and
a carbon content of each of the second fiber yarns is greater than a carbon content of each of the first fiber yarns and a carbon content of each of the third fiber yarns.

10. The display device of claim 1, wherein an elastic modulus of each of the second fiber yarns is greater than an elastic modulus of each of the first fiber yarns and an elastic modulus of each of the third fiber yarns.

11. A display device comprising:
a display panel having a folding axis extending in a first direction; and
a panel supporter disposed on a surface of the display panel, wherein
the panel supporter includes:
a first layer including a first base resin and first fiber yarns, the first fiber yarns extending in the first direction and dispersed in the first base resin;
a second layer disposed on the first layer, the second layer including a second base resin and second fiber yarns, the second fiber yarns extending in a second direction intersecting the first direction and dispersed in the second base resin; and
a third layer disposed on the second layer, the third layer including a third base resin and third fiber yarns, the third fiber yarns extending in the first direction and dispersed in the third base resin, and
an elastic modulus of each the second fiber yarns is greater than an elastic modulus of each of the first fiber yarns and an elastic modulus of each of the third fiber yarns.

12. The display device of claim 11, wherein the elastic modulus of each of the first fiber yarns and the elastic modulus of each of the third fiber yarns are same as each other.

13. The display device of claim 12, wherein a thickness of the second layer is greater than a thickness of the first layer and a thickness of the third layer.

14. The display device of claim 13, wherein the second layer is disposed between the first layer and the third layer.

15. The display device of claim 14, wherein
the elastic modulus of each of the second fiber yarns is about 290 GPa or more, and
the elastic modulus of each of the first fiber yarns and the elastic modulus of each of the third fiber yarns are about 240 GPa or less.

16. A display device comprising:
a display panel having a folding axis extending in a first direction; and
a panel supporter disposed on a surface the display panel, wherein
the panel supporter includes:
a first layer including a first base resin and first fiber yarns extending in the first direction and dispersed in the first base resin;
a second layer disposed on the first layer, the second layer including a second base resin and second fiber yarns extending in a second direction intersecting the first direction and dispersed in the second base resin; and
a third layer disposed on the second layer, the third layer including a third base resin and third fiber yarns extending in the first direction and dispersed in the third base resin, and
wherein a carbon content of each of the second fiber yarns is greater than a carbon content of each of the first fiber yarns and a carbon content of each of the third fiber yarns.

17. The display device of claim 16, wherein the carbon content of each of the first fiber yarns and the carbon content of each of the third fiber yarns are same as each other.

18. The display device of claim 17, wherein a thickness of the second layer is greater than a thickness of the first layer and a thickness of the third layer.

19. The display device of claim 18, wherein the second layer is disposed between the first layer and the third layer.

20. The display device of claim 19, wherein
the carbon content of each of the second fiber yarns is about 96% or more, and
the carbon content of each of the first fiber yarns and the carbon content of each of the third fiber yarns are about 93% or less.

21. A display device comprising:
a display panel having a folding axis extending in a first direction; and
a panel supporter disposed on a surface of the display panel and including a base resin and fiber yarns dispersed in the base resin, wherein
the fiber yarns include:
first fiber yarns extending in the first direction;
second fiber yarns extending in a second direction intersecting the first direction; and
third fiber yarns extending in the first direction,
the base resin includes:
a first portion in which the first fiber yarns are dispersed;
a second portion disposed on the first portion, the second fiber yarns being dispersed in the second portion; and
a third portion disposed on the second portion, the third fiber yarns being dispersed in the third portion, and
the number of the second fiber yarns per unit volume of the second portion is greater than the number of the first fiber yarns per unit volume of the first portion and the number of the third fiber yarns per unit volume of the third portion.

22. The display device of claim 21, wherein a diameter of each of the second fiber yarns is smaller than a diameter of each of the first fiber yarns and a diameter of each of the third fiber yarns.

23. The display device of claim 22, wherein a spaced distance between the second fiber yarns in the second portion is smaller than a spaced distance between the first fiber yarns in the first portion and a spaced distance between the third fiber yarns in the third portion.
